(19) United States
(12) Patent Application Publication
(10) Pub. No.: US 2011/0108792 A1
(43) Pub. Date: May 12, 2011

(54) Single Crystal Phase Change Material

(75) Inventors: Chung Hon Lam, Yorktown Heights, NY (US); Alejandro G. Schrott, Yorktown Heights, NY (US); Chieh-Fang Chen, Yorktown Heights, NY (US)

(73) Assignees: INTERNATIONAL BUSINESS MACHINES CORPORATION, Armonk, NY (US); Macronix International Co., Ltd., Hsinchu (TW)

(21) Appl. No.: 12/616,492

(22) Filed: Nov. 11, 2009

(51) Int. Cl. H01L 45/00; H01L 21/28

(52) U.S. Cl. 257/3; 438/102; 257/E45.002; 257/E21.158

(57) ABSTRACT

A method for fabricating a phase change memory (PCM) cell includes forming a dielectric layer over an electrode, the electrode comprising an electrode material; forming a via hole in the dielectric layer such that the via hole extends down to the electrode; and growing a single crystal of a phase change material on the electrode in the via hole. A phase change memory (PCM) cell includes an electrode comprising an electrode material; a dielectric layer over the electrode; a via hole in the dielectric layer; and a single crystal of a phase change material located in the via hole, the single crystal contacting the electrode at the bottom of the via hole.

### FIELD

This disclosure relates generally to the field of phase change memory (PCM) fabrication.

### DESCRIPTION OF RELATED ART

Phase-change memory (PCM) is a type of non-volatile computer memory. PCM stores data in cells comprising a phase change material, which can be switched between two distinct states, i.e., crystalline and amorphous, with the application of heat. The phase change material may be deposited and patterned to form individual PCM cells. However, as PCM cells become smaller, it becomes difficult to pattern the cells using etching techniques such as reactive ion etching (RIE), as RIE may change the chemical makeup of the phase change material within a region of about 10 nm from the feature's edge, which may preclude following the scaling road map since the damaged region would constitute all the material in left in the cell for small dimensions.

Alternately, a small amount of phase change material may be deposited in a small hole, or via, to form an individual PCM cell. Chemical vapor deposition (CVD) and atomic layer deposition (ALD) methods may be used to deposit the phase change material. However, these methods may produce polycrystalline phase change material with crystals larger than the size of the via hole, which may not properly fill the via hole, or amorphous phase change material which may form voids and loose contact with an electrode located at the bottom of the via hole upon crystallization, as the phase change material may shrink as it changes from the amorphous state to the crystalline state.

### SUMMARY

In one aspect, a method for fabricating a phase change memory (PCM) cell includes forming a dielectric layer over an electrode, the electrode comprising an electrode material; forming a via hole in the dielectric layer such that the via hole extends down to the electrode; and growing a single crystal of a phase change material on the electrode in the via hole.

In one aspect, a phase change memory (PCM) cell includes an electrode comprising an electrode material; a dielectric layer over the electrode; a via hole in the dielectric layer; and a single crystal of a phase change material located in the via hole, the single crystal contacting the electrode at the bottom of the via hole.

In one aspect, a phase change memory (PCM) array comprising a plurality of cells, each cell including an electrode comprising an electrode material; a dielectric layer over the electrode; a via hole in the dielectric layer; and a single crystal of a phase change material located in the via hole, the single crystal contacting the electrode at the bottom of the via hole.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of a method for formation of single crystal phase change material.

FIG. 2 illustrates a cross-section of an embodiment of a process for formation of single crystal phase change material.

FIG. 3 illustrates a cross-section of an embodiment of a process for formation of single crystal phase change material after formation of a recess in the electrode.

FIG. 4 illustrates a cross-section of an embodiment of a process for formation of single crystal phase change material after formation of a recess in the oxide region.

FIG. 5 illustrates a cross-section of an embodiment of a process for formation of single crystal phase change material after formation of a dielectric layer and a keyhole.

FIG. 6 illustrates a cross-section of an embodiment of a process for formation of single crystal phase change material after formation of a via hole.

FIG. 7 illustrates a cross-section of an embodiment of a process for formation of single crystal phase change material after deposition of a single crystal phase change material in the via hole.

FIG. 8 illustrates a cross-section of an embodiment of a process for formation of single crystal phase change material after polishing.

FIG. 9 illustrates a cross-section of an embodiment of a process for formation of single crystal phase change material after formation of a recess in the polycrystalline phase change material, formation of a conductive layer in the recess, and polishing.

FIG. 10 illustrates a cross-section of an embodiment of a process for formation of single crystal phase change material after formation of oxide and transparent electrical conductor layers.

### DETAILED DESCRIPTION

Embodiments of systems and methods for formation of single crystal phase change material are provided, with exemplary embodiments being discussed below in detail.

A single crystal of a phase change material may be grown on an electrode inside a via hole, filling the via hole and preventing void formation between the phase change material crystal and the electrode. The single crystal phase change material may be formed using CVD or ALD methods. The electrode material and the CVD/ALD precursors used to form the phase change material may be chosen such that the precursors used to form the phase change material react with the electrode material, and selective crystalline growth of the phase change material occurs directly on the electrode. The phase change material may also be selected such that the precursors do not react with a dielectric layer in which the via hole is formed. In some embodiments, the electrode may comprise tungsten (W) or titanium nitride (TiN), and the phase change material may comprise a combination of germanium (Ge), antimony (Sb), tellurium (Te) or selenium (Se).

A phase change material has a typical crystal size that will vary depending on the material and temperature on which the crystal is grown. In a via hole larger than the typical crystal size for a chosen phase change material, electrode material, and temperature, a poly crystal may be formed, which may not properly fill the via hole. However, in a via hole smaller than the typical crystal size for the chosen phase change material and electrode material, a single crystal may be formed. Therefore, the via hole may be formed such that it is smaller than a typical crystal size of the chosen phase change material when that phase change material is grown on the chosen electrode material at a chosen temperature. For instance, for Ge₂Sb₂Te₅(GST) deposited by CVD inside a via of a 200 nm CD with a W bottom electrode, at about 300° C., the typical crystal size is about 80 nm. For similar conditions, the typical crystal size for GeTe is about 120 nm.

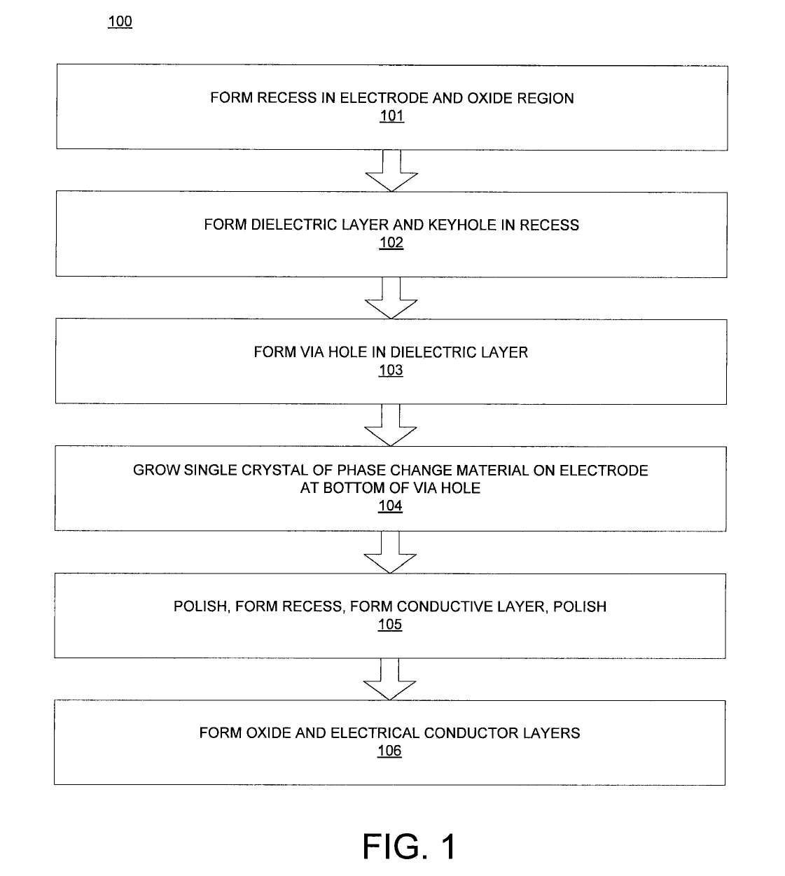

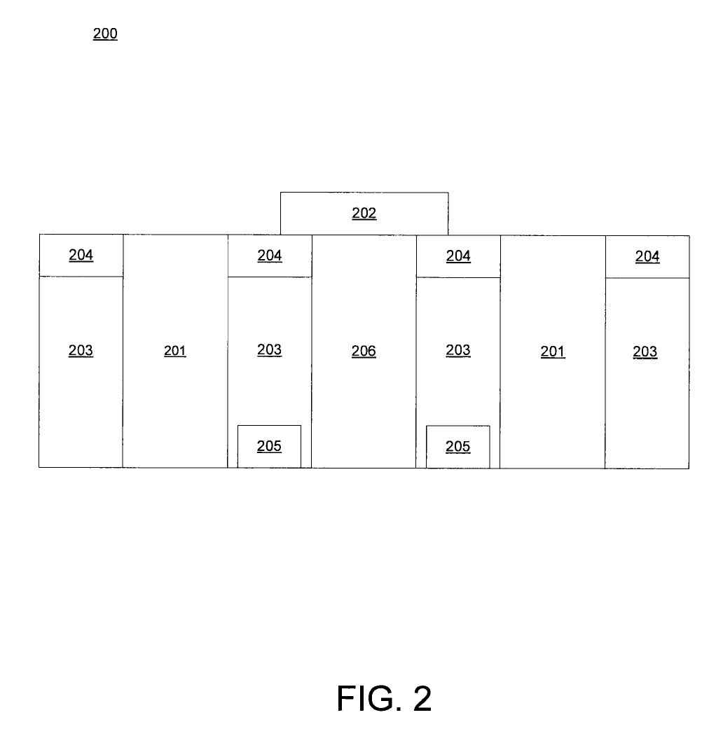

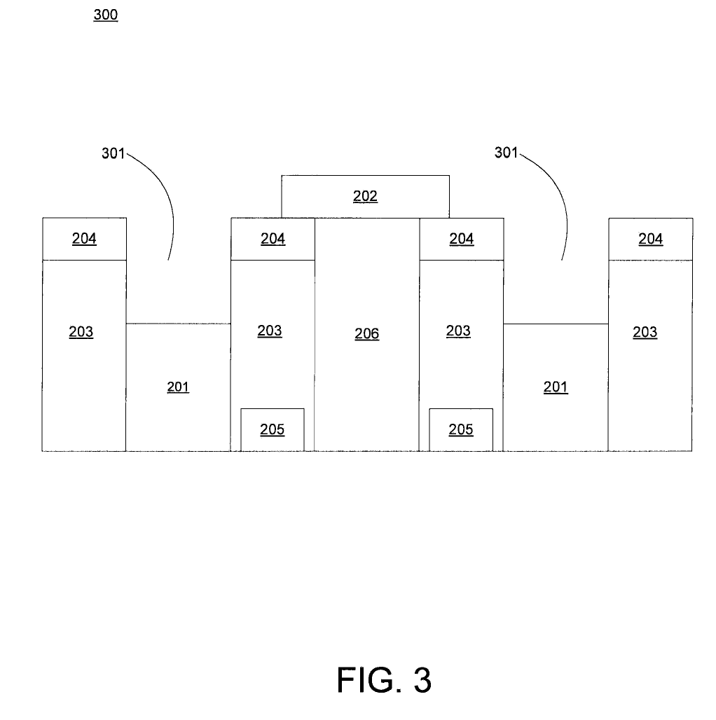

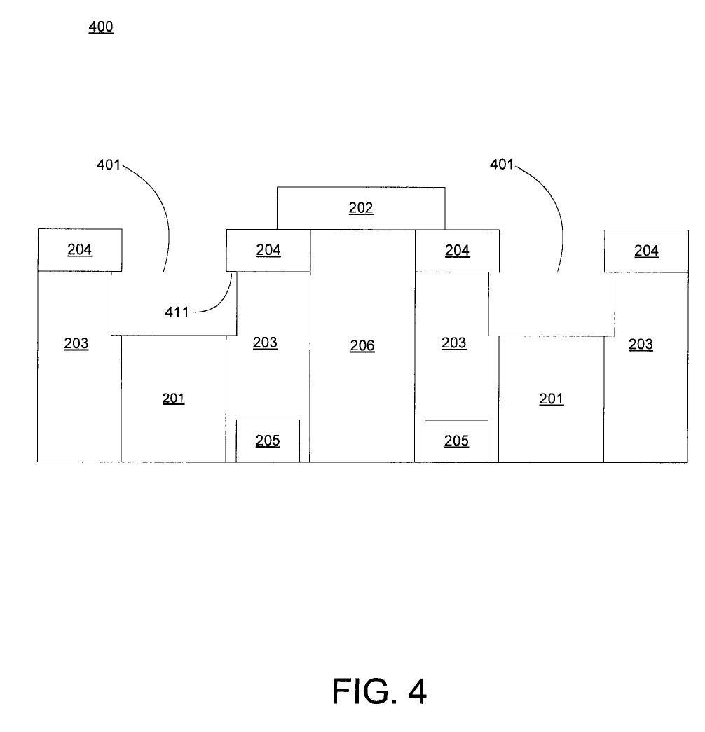

FIG. 1 illustrates an embodiment of a method 100 for formation of single crystal phase change material. FIG. 1 is discussed with reference to FIGS. 2-10. As shown in cross-section 200 of FIG. 2, PCM word lines 205 are located in oxide regions 203, which are underneath nitride regions 204. Electrodes 201 may comprise tungsten (W) or titanium nitride (TiN), and are located in between oxide regions 203. Electrodes 201 connect to the front end of line (FEOL) portion of the PCM. Protection bar 202 protects electrode 206 (which connects to a terminal of a row of selecting transistors, not shown). In block 101, recesses 301 (as shown in cross-section 300 of FIG. 3) are formed in electrodes 201, and recesses 401 including overhang 411 (as shown in cross-section 400 of FIG. 4) are extended into oxide regions 203. Recesses 301 and 401 may be formed by any appropriate etching technique.

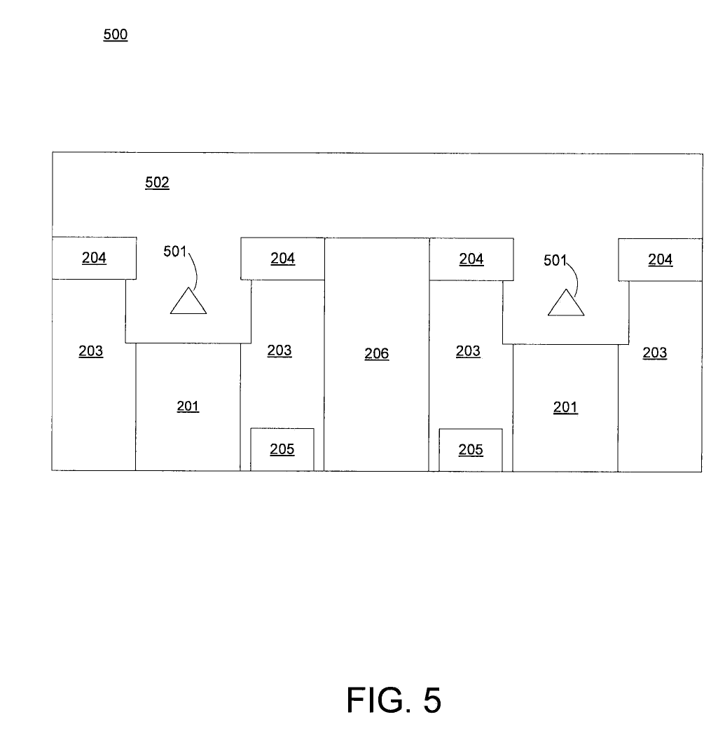

In block 102, dielectric layer 502 is formed by a conformal deposition, as shown in cross-section 500 of FIG. 5. Dielectric layer 502 fills recesses 401, and comprises keyholes 501. In some embodiments, dielectric layer 502 may comprise one of conformal oxide or silicon. Keyholes 501 may have a maximum width about equal to twice the width of overhang 411 in recess 401.

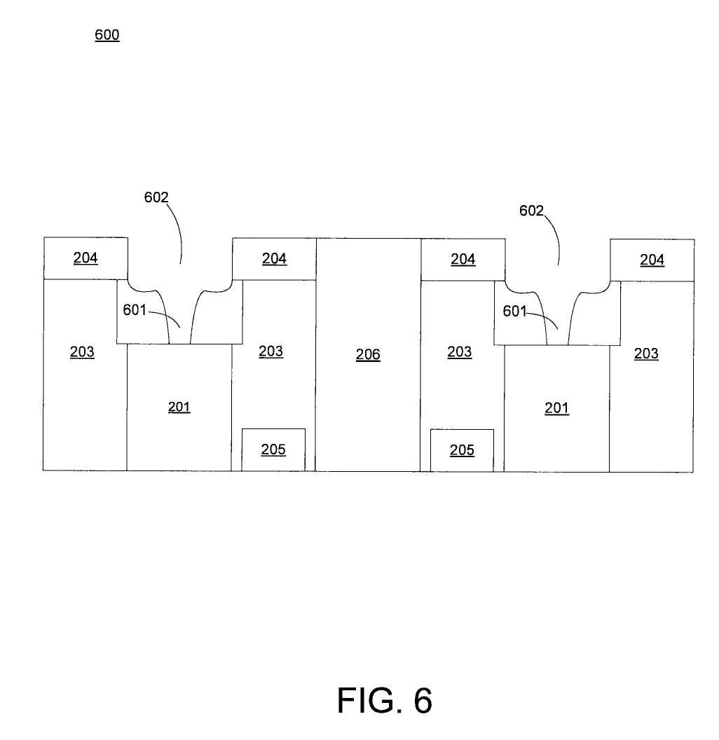

In block 103, via holes 601 and via hole collars 602 are formed in dielectric layer 502, as shown in cross-section 600 FIG. 6. Via holes 601 and via hole collars 602 may be formed by RIE of dielectric layer 502 through keyholes 501. Keyholes 501 act as a hard mask during RIE. The diameter of keyholes 501 determine the diameter of via holes 601. The via holes 601 extend down to electrodes 201, and have a diameter smaller than a typical crystal size of a phase change material (discussed in further detail with respect to block 104 below) when it is grown on the material that comprises electrodes 201. Because the current density is higher in the via holes 601, switching of the phase change material between the amorphous and crystalline states due to Joule heating will occur within via holes 601.

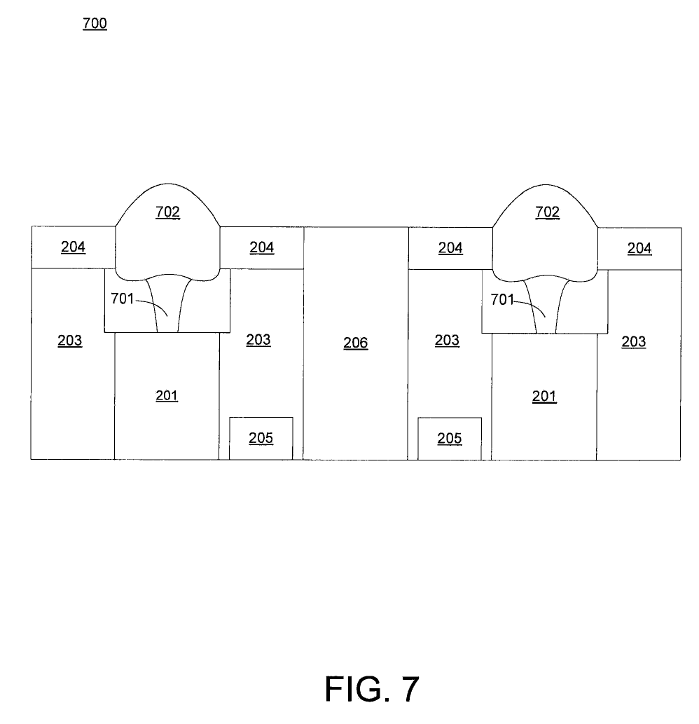

In block 104, a phase change material 701 is deposited in the via holes 601, as shown in cross-section 700 of FIG. 7. Phase change material 701 comprises a single crystal of a phase change material, which may comprise a combination of germanium (Ge), antimony (Sb), tellurium (Te) or selenium (Se). Phase change material 701 may be formed using CVD or ALD methods. The CVD/ALD precursors used to form phase change material 701 and the material comprising electrode 201 are chosen such that selective crystalline growth of phase change material 701 occurs directly on electrode 201 in via hole 601. Polycrystalline phase change material 702 (comprising the same material as phase change material 701) is also formed in the via hole collars 602.

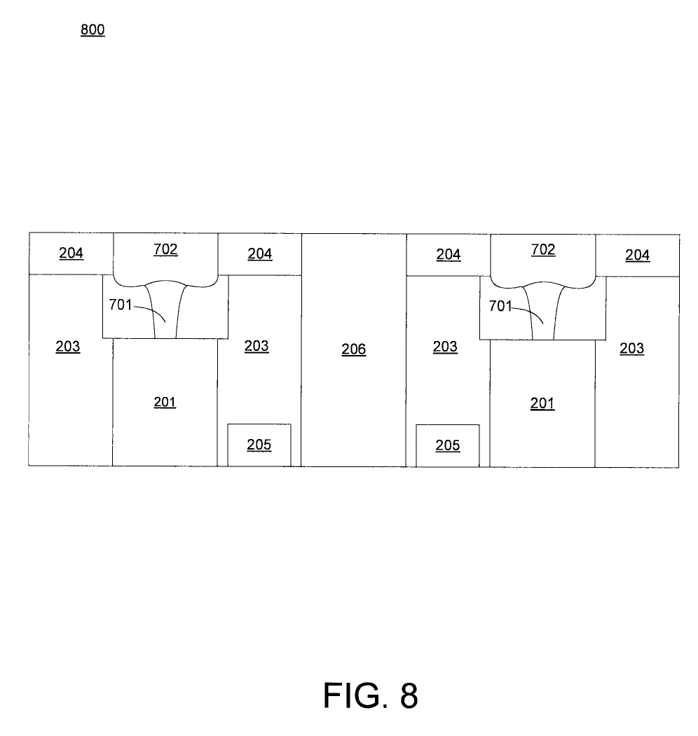

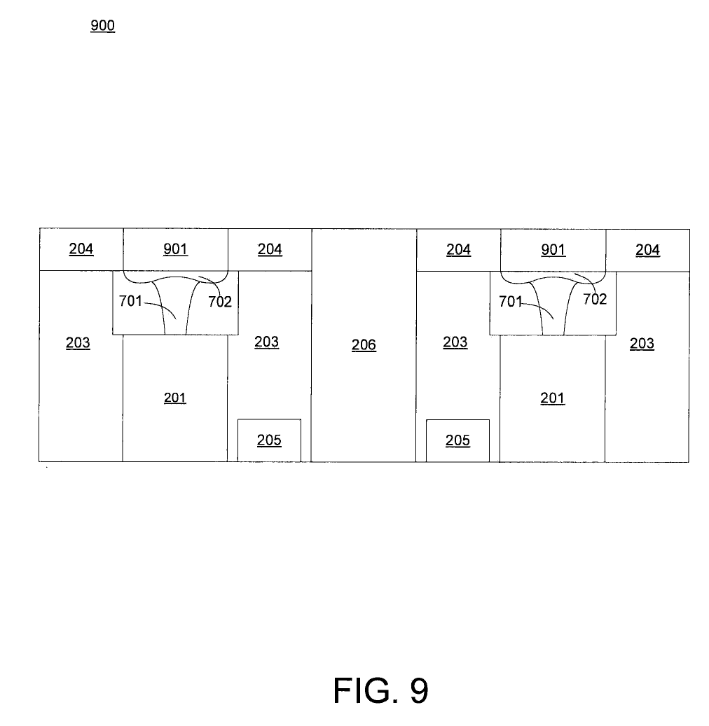

In block 105, the surface comprising nitride 204 and polycrystalline phase change material 702 is polished, as is shown in cross-section 800 of FIG. 8. A recess is then formed in polycrystalline phase change material 702, and conductive layer 901 is formed in the recess, and the surface comprising nitride 204 and conductive layer 901 is polished, as is shown in cross-section 900 of FIG. 9. Conductive layer 901 may comprise titanium nitride in some embodiments. Polishing may be performed using chemical mechanical polishing (CMD).

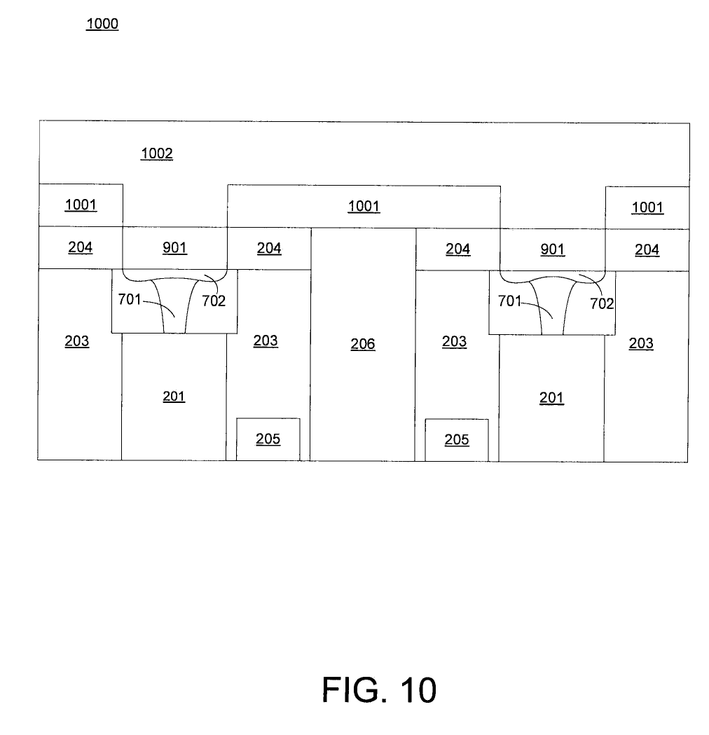

In block 106, oxide layers 1001 and electrical conductor layers 1002 are formed, as is shown in PCM cross-section 1000 of FIG. 10. PCM 1000 comprises single crystal phase change material 701 contacting electrodes 201, which prevents formation of voids between the phase change material 701 and electrodes 201 when the phase change material 701 switches between the amorphous state and the crystalline state.

The technical effects and benefits of exemplary embodiments include formation of relatively small PCM cells while preventing void formation between the phase change material and the electrodes that comprise the PCM cells within the switching region.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method for fabricating a phase change memory (PCM) cell, the method comprising:
forming a dielectric layer over an electrode, the electrode comprising an electrode material;
forming a via hole in the dielectric layer such that the via hole extends down to the electrode; and
growing a single crystal of a phase change material on the electrode in the via hole.

2. The method of claim 1, wherein the phase change material has a typical crystal size when it is grown on the electrode material at a specified temperature; and
wherein a diameter of the via hole is smaller than the typical crystal size.

3. The method of claim 1, wherein growing a single crystal of a phase change material on the electrode in the via hole comprises atomic layer deposition.

4. The method of claim 1, wherein growing a single crystal of a phase change material on the electrode in the via hole comprises chemical vapor deposition.

5. The method of claim 1, wherein the electrode material comprises one of tungsten or titanium nitride.

6. The method of claim 1, wherein the phase change material comprises one or more of germanium, antimony, tellurium, or selenium.

7. The method of claim 1, wherein the phase change material is formed using a plurality of precursors, and the plurality of precursors are selected such that the precursors react with the electrode material.

8. The method of claim 1, wherein the phase change material is formed using a plurality of precursors, and the plurality of precursors are selected such that the precursors do not react with the dielectric material.

9. The method of claim 1, wherein the dielectric layer comprises a keyhole, and forming a via hole in the dielectric layer comprises reactive ion etching the dielectric layer through the keyhole.

10. The method of claim 9, wherein a diameter of the keyhole determines a diameter of the via hole.

11. A phase change memory (PCM) cell, comprising:
an electrode comprising an electrode material;
a dielectric layer over the electrode;
a via hole in the dielectric layer; and
a single crystal of a phase change material located in the via hole, the single crystal contacting the electrode at the bottom of the via hole.

12. The PCM cell of claim 11, wherein the phase change material has a typical crystal size when it is grown on the electrode material at a specified temperature; and
wherein a diameter of the via hole is smaller than the typical crystal size.

13. The PCM cell of claim 11, wherein growing a single crystal of a phase change material on the electrode in the via hole comprises atomic layer deposition.

14. The PCM cell of claim 11, wherein growing a single crystal of a phase change material on the electrode in the via hole comprises chemical vapor deposition.

15. The PCM cell of claim 11, wherein the electrode material comprises one of tungsten or titanium nitride.

16. The PCM cell of claim 11, wherein the phase change material comprises one or more of germanium, antimony, tellurium, or selenium.

17. The PCM cell of claim 11, wherein the phase change material is formed using a plurality of precursors, and the plurality of precursors are selected such that the precursors react with the electrode material.

18. The PCM cell of claim 11, wherein the phase change material is formed using a plurality of precursors, and the plurality of precursors are selected such that the precursors does not react with the dielectric material.

19. A phase change memory (PCM) array comprising a plurality of cells, each cell comprising:
an electrode comprising an electrode material;
a dielectric layer over the electrode;
a via hole in the dielectric layer; and
a single crystal of a phase change material located in the via hole, the single crystal contacting the electrode at the bottom of the via hole.

20. The PCM array of claim 19, wherein the phase change material has a typical crystal size when it is grown on the electrode material at a specified temperature; and
wherein a diameter of the via hole is smaller than the typical crystal size.
